(19) United States
(12) Patent Application Publication
(10) Pub. No.: US 2013/0163311 A1
(43) Pub. Date: Jun. 27, 2013

(54) SEMICONDUCTOR STORAGE DEVICE

(71) Applicant: FUJITSU LIMITED, Kawasaki-shi (JP)

(72) Inventors: Yukitoshi HANAFUSA, Yokohama (JP); Gaku ITO, Kawasaki (JP)

(73) Assignee: FUJITSU LIMITED, Kawasaki-shi (JP)

(21) Appl. No.: 13/771,312

(22) Filed: Feb. 20, 2013

Related U.S. Application Data
(63) Continuation of application No. PCT/JP2010/005246, filed on Aug. 25, 2010.

(51) Int. Cl. G11C 7/00

(52) U.S. Cl. CPC G11C 7/00
USPC 365/154

(57) ABSTRACT

A semiconductor storage device comprises a memory cell array having memory cells each configured to hold data, a plurality of N ports, a port selection circuit that selects M (M<N) ports from among the plurality of N ports based on input select signal and a read and write circuit that reads data from the memory cell array or writes data to the memory cell array using the ports selected by the port selection circuit.

### CROSS-REFERENCE TO RELATED APPLICATION

This is a continuation of Application No. PCT/JP2010/005246, filed on Aug. 25, 2010, the entire contents of which are incorporated herein by reference.

### FIELD

The embodiments discussed herein are related to a technique for suppressing a reduction in yield and performance caused by manufacturing variations and deterioration of a static random access memory (SRAM) circuit included in a large scale integration (LSI) device.

### BACKGROUND

In order to suppress a reduction in yield and performance caused by manufacturing variations among SRAM circuits included in LSI devices, SRAM circuits include redundant memory cells and circuits associated with the memory cells, and the redundant circuits are selectively used.

Specifically, an SRAM circuit includes redundant memory cell rows or columns for the SRAM circuit. Six-transistor (6Tr) memory cells are generally used as memory cells in an SRAM circuit. A 6Tr memory cell has a configuration in which a data holding portion and a bit line are directly coupled via a transistor when the word line WL goes high (H), and has a characteristic that data is likely to be unstably held. To address this characteristic, a memory cell array is often divided to reduce the load on individual bit lines. Dividing a memory cell array may reduce the number of memory cells to be connected to a single bit line. Further, dividing a memory cell array reduces the number of memory cells to be connected to a single bit line and also reduces the length of the bit line, although there is a tendency for the area of the SRAM circuit to increase.

In the case of divided bit-line SRAM circuits, a single-end SRAM circuit is increasingly selected rather than a differential SRAM circuit because a large bit line amplitude may be attained for a read circuit.

In an SRAM circuit which employs single-end reading, right and left, or two, bit lines are available, and in this case the number of memory cell ports is presumably two.

Because of the structure of a 6Tr memory cell, writing from one transmission transistor is difficult, and in general both transmission transistors are concurrently used. For this reason, even if one read port is sufficient, the memory cell employs right and left, or two, transmission transistors for writing, and it is difficult to reduce the number of transmission transistors. Consequently, one port may be redundant when data is read.

The demand for increased capacity of SRAM circuits included in LSI devices has increased to improve the performance of LSI devices, and a reduction in the area of SRAM circuits has become a challenging issue. On the other hand, taking a measure against the reduction in yield and performance caused by manufacturing variations and deterioration, such as providing additional redundant circuits and dividing a memory cell array, as described above, may increase the area of an SRAM circuit. When there are a plurality of memory cell ports, some ports may malfunction due to manufacturing variations and deterioration, or performance may deteriorate. That is, main transistors that affect the performances of reading from bit lines A and B are different, and influences such as manufacturing variations may cause a problem of there being a difference in performance between the bit lines A and B.

Japanese Laid-open Patent Publication No. 62-262294 and Japanese Laid-open Patent Publication No. 5-166375 are examples of the related art.

The embodiments described herein provide a semiconductor storage device which implements a redundancy method that may suppress an increase in the area thereof by using a port that is redundant in the operation of the semiconductor storage device when no problems arise in the holding functionality of memory cells provided in the semiconductor storage device.

### SUMMARY

According to an aspect of the invention, a semiconductor storage device comprises a memory cell array having memory cells each configured to hold data, a plurality of N ports, a port selection circuit that selects M (M<N) ports from among the plurality of N ports based on input select signal and a read and write circuit that reads data from the memory cell array or writes data to the memory cell array using the ports selected by the port selection circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a principle diagram of an SRAM circuit according to an embodiment;

FIG. 2 is a configuration diagram of a built-in self-test (BIST) circuit for testing the SRAM circuit according to the embodiment;

FIG. 3 illustrates a port selection test procedure for the SRAM circuit according to the embodiment;

FIG. 4 is a configuration diagram of a SRAM using 6Tr memory cells according to an embodiment;

FIG. 5 is a configuration diagram of an A/B selection circuit according to the embodiment;

FIGS. 6A and 6B are timing charts illustrating an operation waveform of the SRAM using 6Tr memory cells according to the embodiment;

FIG. 7 is a configuration diagram of a SRAM using 6Tr memory cells according to an embodiment;

FIG. 8 is a configuration diagram of an A/B selection circuit according to the embodiment;

FIG. 9 is a configuration diagram of a SRAM using 6Tr memory cells according to an embodiment;

FIG. 10 is a configuration diagram of an A/B selection circuit according to the embodiment;

FIG. 11 is a configuration diagram of a SRAM using 6Tr memory cells according to an embodiment; and

FIG. 12 is a configuration diagram of a SRAM using 6Tr memory cells according to an embodiment.

### DESCRIPTION OF EMBODIMENTS

Embodiments disclosed herein will be described in the context of an SRAM circuit that is a semiconductor storage device.

An SRAM circuit is configured to select some of a plurality of redundant ports arranged in memory cells constituting the SRAM circuit, and read or write data using the selected ports. Making the redundant ports of the memory cells selectively usable to read or write data may suppress a reduction in yield and performance of LSI including the SRAM circuit without providing the SRAM circuit with redundant memory cells.

A specific example will now be described.

1. Principle Diagram of SRAM Circuit 100

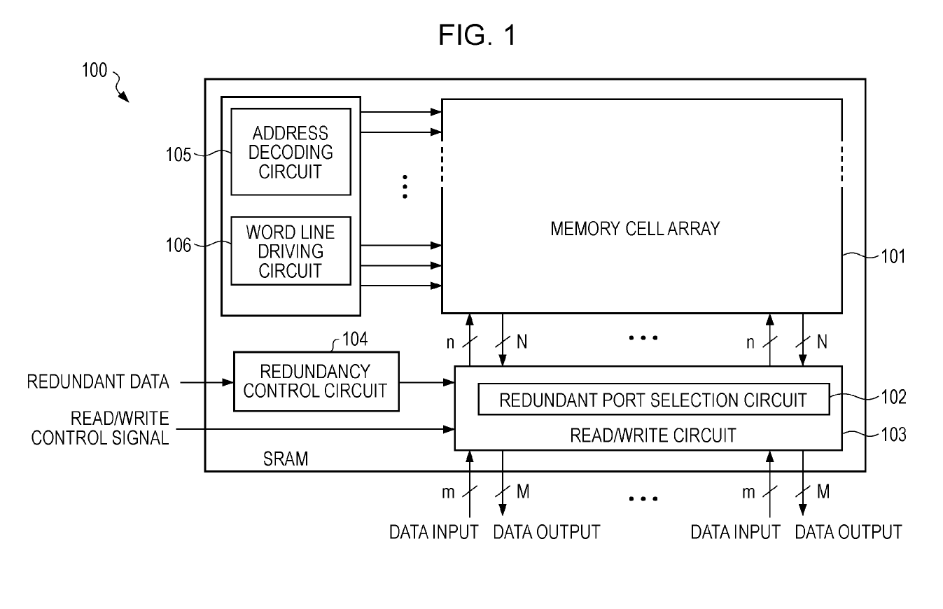

FIG. 1 is a principle diagram of an SRAM circuit 100 according to an embodiment. The SRAM circuit 100 is an SRAM circuit mounted on, for example, a central processing unit (CPU) and used as a cache memory. The SRAM circuit 100 includes a memory cell array 101, a redundant port selection circuit 102, a read/write circuit 103, a redundancy control circuit 104, an address decoding circuit 105, and a word line driving circuit 106.

The memory cell array 101 has an array of memory cells each having a data holding function. The memory cells are semiconductor memories and are circuit elements used to hold information of 1 bit which is the minimum information unit of “0” or “1”.

The redundant port selection circuit 102 is a circuit that selects some of a plurality of redundant ports arranged in the memory cells. In this embodiment, the redundant port selection circuit 102 selects m ports to be actually used for data writing from among n ports available to write data. The redundant port selection circuit 102 further selects M ports to be actually used for data reading from among N ports available to read data.

The read/write circuit 103 is a circuit that reads or writes data using the ports selected by the redundant port selection circuit 102. Here, the read/write circuit 103 receives a read/write control signal from outside the SRAM circuit 100, and reads or writes data in accordance with the read/write control signal.

The redundancy control circuit 104 receives redundant data from outside the SRAM circuit 100, and controls the redundant port selection circuit 102 to select ports using the redundant data.

The address decoding circuit 105 is a circuit that activates, in accordance with an address input received from outside the SRAM circuit 100, access to a memory cell instructed by the address input.

The word line driving circuit 106 drives a word line connected to memory cells in the memory cell array 101 to make operable the memory cells connected to the word line.

2. Configuration of BIST Circuit 200

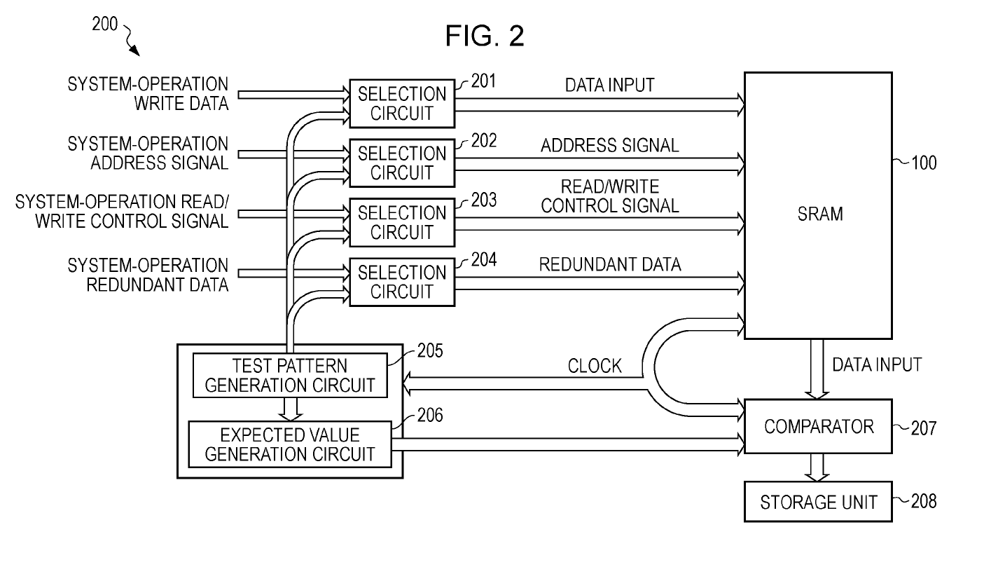

FIG. 2 is a configuration diagram of a built-in self-test (BIST) circuit 200 for testing the SRAM circuit 100 according to this embodiment. The BIST circuit 200 includes selection circuits 201, 202, 203, and 204, a test pattern generation circuit 205, an expected value generation circuit 206, and a comparator 207.

The selection circuit 201 inputs data to the SRAM circuit 100, and the selection circuit 202 inputs an address signal indicating the address from which the data is to be read or the address to which the data is to be written to the SRAM circuit 100. The selection circuit 203 inputs a read/write control signal for controlling reading or writing of the data from or to the SRAM circuit 100 to the SRAM circuit 100, and the selection circuit 204 inputs redundant data used to select ports to be used to read or write the data from among redundant ports to the SRAM circuit 100.

The selection circuit 201 receives system-operation write data and a test pattern. The selection circuit 202 receives a system-operation address signal and a test pattern. The selection circuit 203 receives a system-operation read/write control signal and a test pattern. The selection circuit 204 receives system-operation redundant data and a test pattern.

The test pattern generation circuit 205 generates the test patterns for the data input, the address signal, the read/write control signal, and the redundant data, which are input to the selection circuits 201, 202, 203, and 204, respectively.

The expected value generation circuit 206 generates expected values that will be output from the SRAM circuit 100 with respect to the test patterns generated by the test pattern generation circuit 205.

The comparator 207 compares the expected values generated by the expected value generation circuit 206 with data output from the SRAM circuit 100, and outputs comparison results.

The BIST circuit 200 tests the ports included in the SRAM circuit 100 in terms of operation and performance using the selection circuits 201, 202, 203, and 204, the test pattern generation circuit 205, the expected value generation circuit 206, and the comparator 207, and selects ports to be used for data reading or writing in accordance with the results of the test. The ports to be used for data reading or writing when the SRAM circuit 100 is used are fixedly set in accordance with the test results. The BIST circuit 200 may also be configured to switch the setting, for example, when a port set after the test fails during use.

3. Port Selection Test Procedure

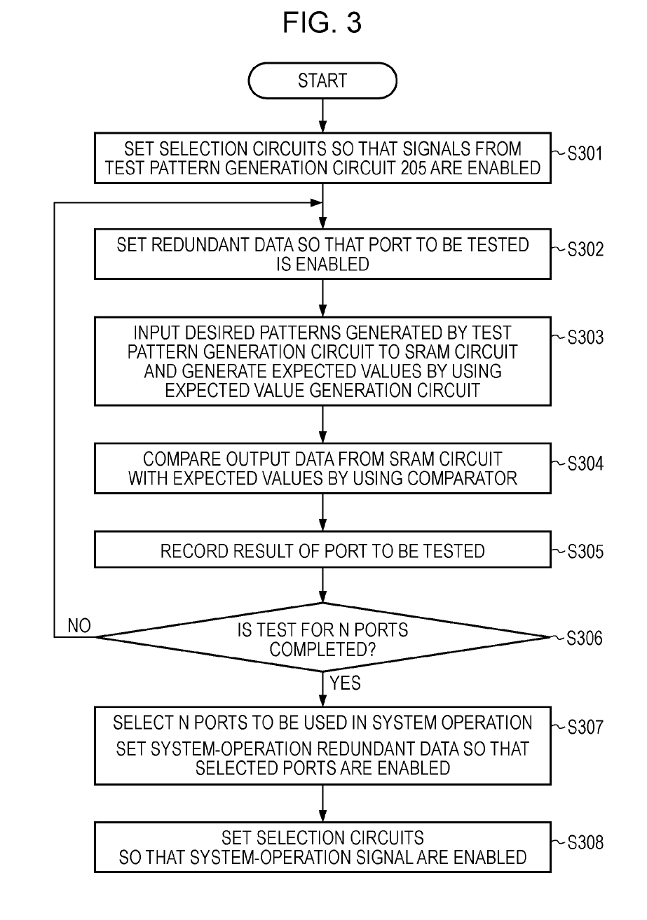

FIG. 3 illustrates a port selection test procedure for the SRAM circuit 100 according to this embodiment. The BIST circuit 200 sets the selection circuits 201, 202, 203, and 204 so that the signals from the test pattern generation circuit 205 are enabled (step S301). As used here, the test pattern generation circuit 205 is a circuit that inputs write data, an address signal, a read/write control signal, and redundant data to the selection circuits 201, 202, 203, and 204, respectively. The BIST circuit 200 sets the redundant data so that the port to be tested is enabled (step S302).

The selection circuits 201 to 204 input the desired patterns generated by the test pattern generation circuit 205 to the SRAM circuit 100. The expected value generation circuit 206 generates expected values (step S303).

The comparator 207 compares data output from the SRAM circuit 100 with the expected values generated by the expected value generation circuit 206 (step S304). The comparator 207 outputs a determination result of the port to be tested, and records the determination result on a storage unit 208 (step S305).

Then, it is determined whether or not the test for the N ports to be used in the system operation has been completed (step S306).

If the test for the N ports to be used in the system operation has been completed (YES in step S306), the selection circuits 201 to 204 select the N ports to be used in the system operation, and set the system-operation redundant data so that the selected N ports are enabled (step S307). Then, the selection circuits 201 to 204 are set so that the system-operation signals are enabled (step S308).

4. Configuration of SRAM Circuit 400

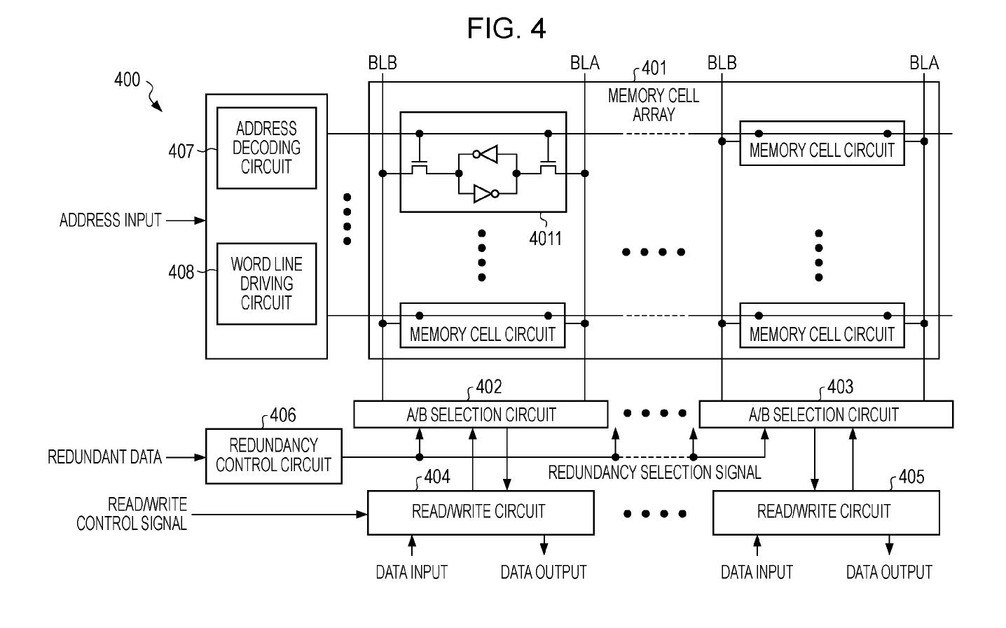

FIG. 4 is a configuration diagram of an SRAM circuit 400 according to an embodiment. In this embodiment, the SRAM circuit 400 is constituted by a 6Tr SRAM memory cell circuit 4011 and a plurality of 6Tr memory cell circuits having configurations equivalent to the configuration of the 6Tr SRAM memory cell circuit 4011.

The SRAM circuit 400 includes a memory cell array 401, A/B selection circuits 402 and 403, read/write circuits 404 and 405, a redundancy control circuit 406, an address decoding circuit 407, and a word line driving circuit 408. The memory cell array 401 is constituted by the 6Tr memory cell circuit 4011 and the plurality of 6Tr memory cell circuits having configurations equivalent to the configuration of the 6Tr memory cell circuit 4011, and the plurality of 6Tr memory cell circuits are arranged in an array.

The A/B selection circuit 402 selects ports to be used for data writing or reading from among redundant ports respectively arranged in the plurality of 6Tr memory cell circuits (including the 6Tr memory cell circuit 4011) constituting the memory cell array 401. The A/B selection circuit 403 is also a circuit that selects ports to be used for data writing or reading from among the redundant ports. The A/B selection circuits 402 and 403 are located at points before write data has reached the memory cell array 401. The A/B selection circuits 402 and 403 are also located after points at which data is read from the memory cell array 401.

The read/write circuits 404 and 405 are circuits that read or write data using the ports selected by the A/B selection circuits 402 and 403. Here, the read/write circuits 404 and 405 receive a read/write control signal from outside the SRAM circuit 400, and read or write data in accordance with the read/write control signal.

The redundancy control circuit 406 receives redundant data from outside the SRAM circuit 400, and controls the A/B selection circuits 402 and 403 to select ports using the redundant data.

The address decoding circuit 407 is a circuit that activates, in accordance with an address input received from outside the SRAM circuit 400, access to a memory cell circuit instructed by the address input.

The word line driving circuit 408 drives word lines connected to the memory cell circuits (including the memory cell circuit 4011) in the memory cell array 401 to make operable the memory cells to which the word lines are connected.

5. A/B Selection Circuits 402 and 403

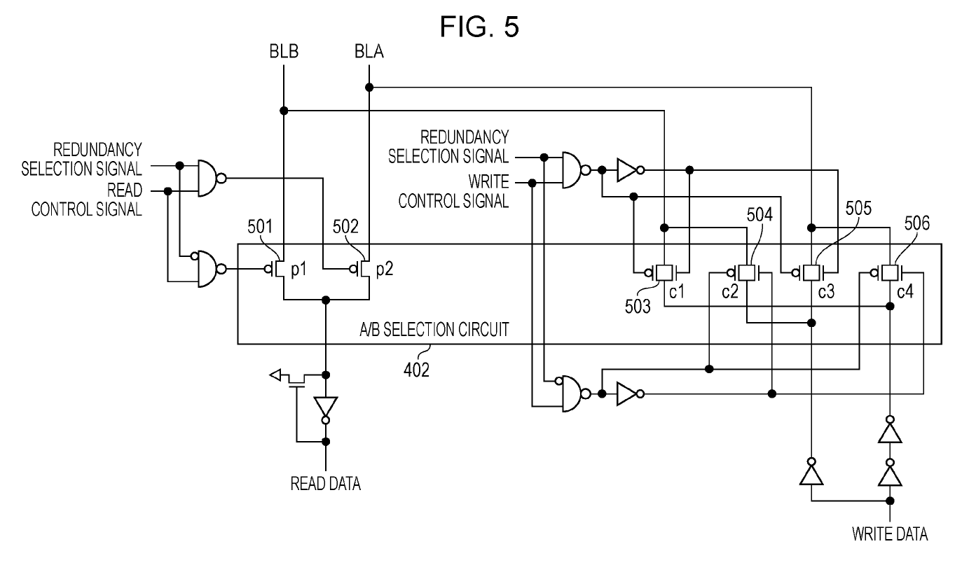

FIG. 5 is a configuration diagram of the A/B selection circuit 402 according to this embodiment. The A/B selection circuit 402 is a circuit that selects ports to be used for data reading or writing. A positive channel metal oxide semiconductor (PMOS) transmission gate 501 constituted by a PMOS transistor is a gate for determining whether or not the ports on the bit line B (BLB) side of the 6Tr memory cell circuits are to be used for data reading. When the PMOS transmission gate 501 is brought into conduction, data is read using the ports on the BLB side.

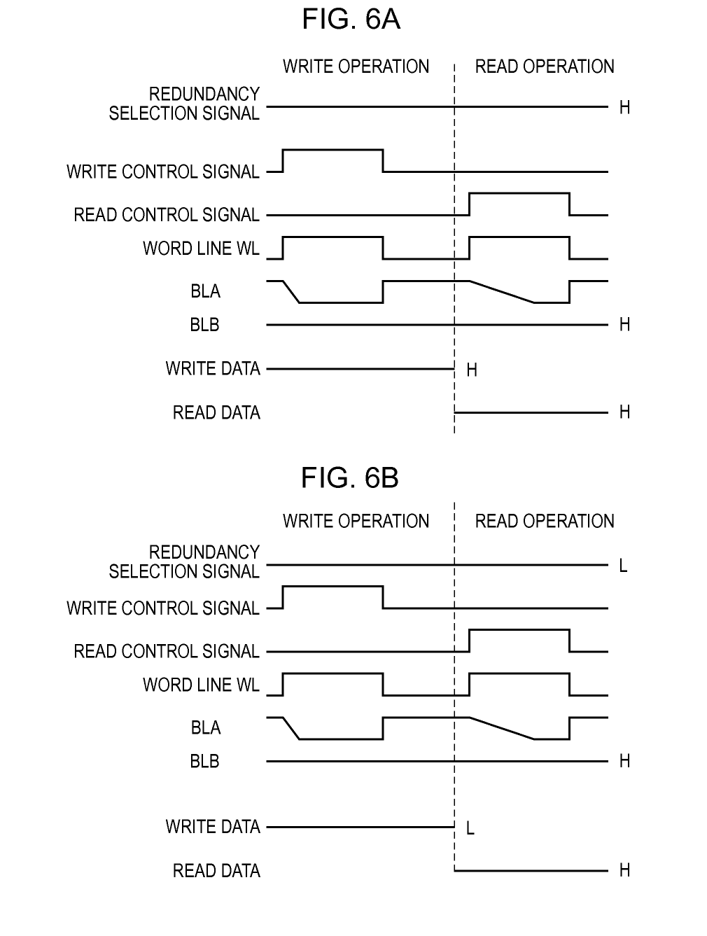

More specifically, a redundancy selection signal is set high (H) and a read control signal is set high (H) (see FIG. 6A), a PMOS transmission gate 502 is brought into conduction, and data is read from the memory cell array 401 using the BLA-side ports. When the redundancy selection signal is set low (L) and the read control signal is set high (H), the PMOS transmission gate 501 is brought into conduction, and data is read from the memory cell array 401 using the BLB-side ports. Similarly, when the redundancy selection signal is set high (H) and the write control signal is set high (H) (see FIG. 6A), the CMOS transmission gate 503 and a CMOS transmission gate 505 are brought into conduction, and the negative logic of the write data (in FIG. 6A, L) is transferred to the BLA while the positive logic of the write data (in FIG. 6A, H) is transferred to the BLB. Further, when the redundancy selection signal is set low (L) and the write control signal is set high (H) (see FIG. 6B), CMOS transmission gates 504 and 506 are brought into conduction, and the positive logic of the write data (in FIG. 6B, H) is transferred to the BLA while the negative logic of the write data (in FIG. 6B, L) is transferred to the BLB.

FIG. 6A illustrates an example in which the BLA and the BLB are charged to high (H) levels before reading, and the BLA becomes low (L) as a result of the word line being selected in accordance with the address and going high (H). The configuration described above allows the A/B selection circuit 402 to make write data and read data match regardless of the redundancy selection signal. The SRAM circuit 400 may be provided with a circuit capable of selecting whether or not the read data is to be inverted in accordance with the redundancy selection signal.

6. Configuration of SRAM Circuit 700

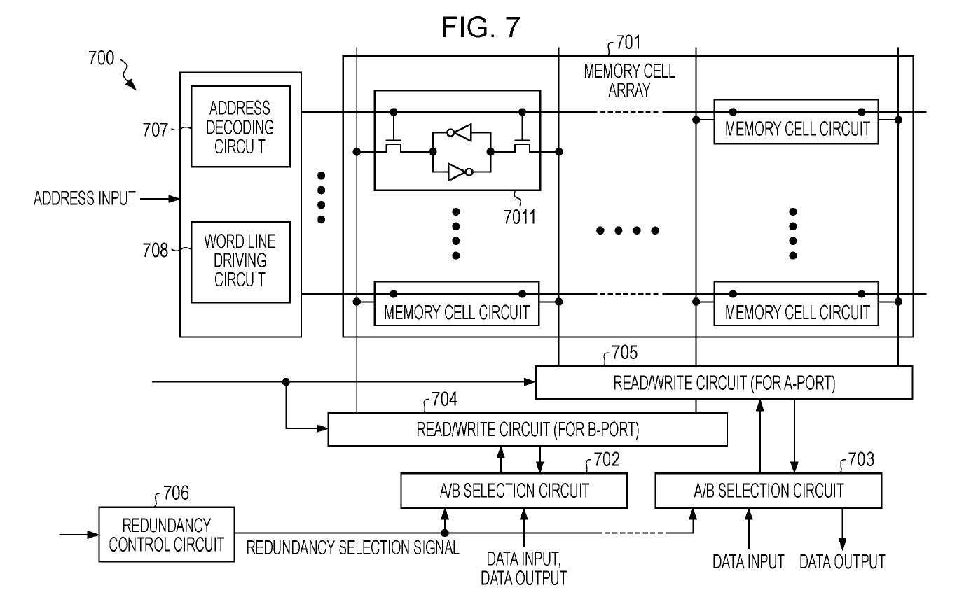

FIG. 7 is a configuration diagram of an SRAM circuit 700 according to an embodiment. The SRAM circuit 700 is configured to select ports after the read data is output from the bit line in order to read data from a memory cell array 701, and to select ports before write data is input to the bit line in order to write data to the memory cell array 701. In the arrangement configuration of the SRAM circuit 700, an A-port read/write circuit 705 and a B-port read/write circuit 704 are redundant, leading to an increase in the area of the SRAM circuit 700; however, a reduction in yield and performance of the SRAM circuit 700 in addition to manufacturing variations and failure of the read/write circuits 704 and 705 may be suppressed.

The SRAM circuit 700 includes the memory cell array 701, A/B selection circuits 702 and 703, the read/write circuits 704 and 705, a redundancy control circuit 706, an address decoding circuit 707, and a word line driving circuit 708. The memory cell array 701 is constituted by a 6Tr memory cell circuit 7011 and a plurality of 6Tr memory cell circuits having configurations equivalent to the configuration of the 6Tr memory cell circuit 7011, and the plurality of 6Tr memory cell circuits are arranged in an array.

The A/B selection circuit 702 selects ports to be used for data writing or reading from among redundant ports respectively arranged in the plurality of 6Tr memory cell circuits (including the 6Tr memory cell circuit 7011) constituting the memory cell array 701. The A/B selection circuit 703 is also a circuit that selects ports to be used for data writing or reading from among the redundant ports.

The read/write circuits 704 and 705 are circuits that read or write data using the ports selected by the A/B selection circuits 702 and 703. Here, the read/write circuits 704 and 705 receive a read/write control signal from outside the SRAM circuit 700, and read or write data in accordance with the read/write control signal.

The redundancy control circuit 706 receives redundant data from outside the SRAM circuit 700, and controls the A/B selection circuits 702 and 703 to select ports using the redundant data.

The address decoding circuit 707 is a circuit that activates, in accordance with an address input received from outside the SRAM circuit 700, access to a memory cell circuit instructed by the address input.

The word line driving circuit 708 drives word lines connected to the memory cell circuits (including the memory cell circuit 7011) in the memory cell array 701 to make operable the memory cells to which the word lines are connected.

7. Configuration of A/B Selection Circuits 702 and 703

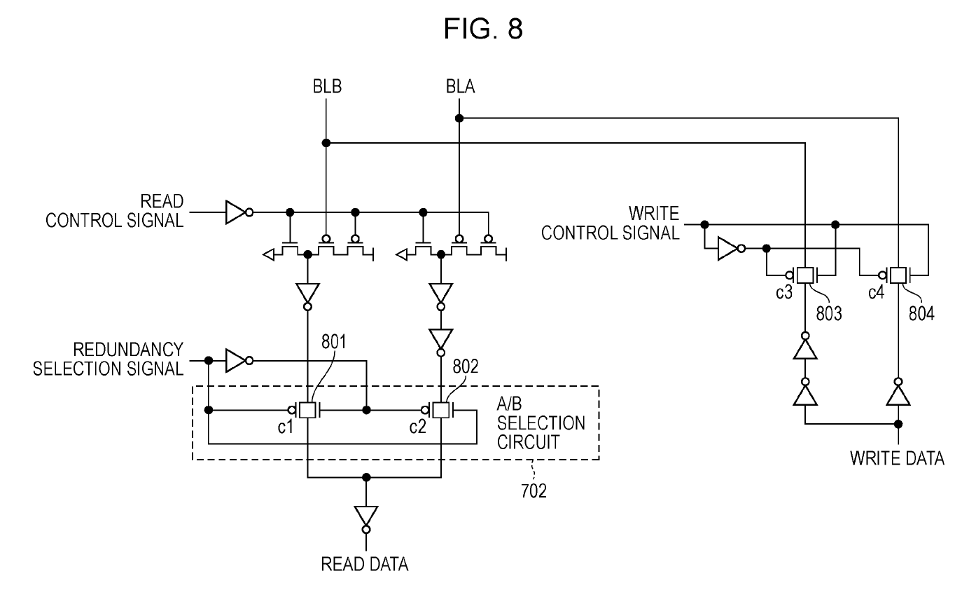

FIG. 8 is a configuration diagram of the A/B selection circuit 702 according to this embodiment. The read/write circuits 704 and 705 are located in stages preceding the A/B selection circuits 702 and 703 according to this embodiment, respectively. When the read control signal becomes high (H), data is read from both the bit lines A (BLA) and B (BLB), and is input to the A/B selection circuits 702 and 703.

Here, the data input to the A/B selection circuits 702 and 703 from one of the bit lines A and B which is selected in accordance with the redundancy selection signal is read data. In the subsequent processing, the data from the selected bit line is output as read data. In the reading operation, the bit line A and the bit line B are complementary. In this embodiment, one additional inverter is provided on the BLA side to allow the same value to be output regardless of which of the bit line A and the bit line B to read from.

For this reason, the data writing process does not involve control based on the redundancy selection signal. In the data reading process, the difference between the reading from the bit line A and the reading from the bit line B because of the provision of the one additional inverter may cause a difference between the data read from the bit line A and the data read from the bit line B. In this case, inversion control may be performed using the redundancy selection signal when data is written.

More specifically, when the read control signal is set high (H), read data is input to CMOS transmission gates 801 and 802. When the redundancy selection signal is set high (H), the CMOS transmission gate 802 is brought into conduction, and data on the bit line A side is read as read data. When the redundancy selection signal is set low (L), the CMOS transmission gate 801 is brought into conduction, and data on the bit line B side is read as read data. When the write control signal is set high (H), CMOS transmission gates 803 and 804 are brought into conduction, and the write data is written to the memory cell array 701 from the bit lines A and B.

8. Configuration of SRAM Circuit 900

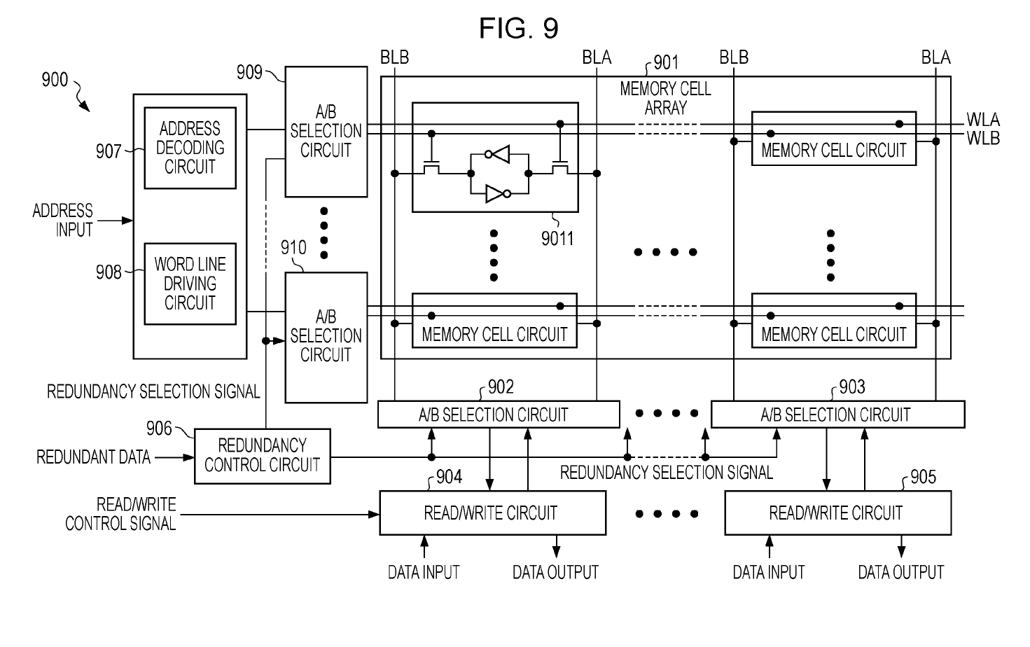

FIG. 9 is a configuration diagram of an SRAM circuit 900 according to an embodiment. In this embodiment, the SRAM circuit 900 is constituted by a 6Tr SRAM memory cell circuit 9011 and a plurality of 6Tr memory cell circuits having configurations equivalent to the configuration of the 6Tr SRAM memory cell circuit 9011. The SRAM circuit 900 is provided with word lines, namely, a word line A (WLA) and a word line B (WLB). The SRAM circuit 900 further includes A/B selection circuits 909 and 910 capable of selecting the word line A or the word line B, and selects the word line A or the word line B in accordance with the ports to be used. Also in the process for writing data to a memory cell array 901, if one of the bit line A and the bit line B is used, the A/B selection circuits 909 and 910 disposed in front of the word lines may suppress the driving of the word line not to be used for data writing.

The SRAM circuit 900 includes the memory cell array 901, A/B selection circuits 902 and 903, read/write circuits 904 and 905, a redundancy control circuit 906, an address decoding circuit 907, a word line driving circuit 908, and the A/B selection circuits 909 and 910. The memory cell array 901 is constituted by the 6Tr memory cell circuit 9011 and a plurality of 6Tr memory cell circuits having configurations equivalent to the configuration of the 6Tr memory cell circuit 9011, and the plurality of 6Tr memory cell circuits are arranged in an array.

The A/B selection circuit 902 selects ports to be used for data writing or reading from among redundant ports respectively arranged in the plurality of 6Tr memory cell circuits (including the 6Tr memory cell circuit 4011) constituting the memory cell array 901. The A/B selection circuit 903 is also a circuit that selects ports to be used for data writing or reading from among the redundant ports.

The read/write circuits 904 and 905 are circuits that read or write data using the ports selected by the A/B selection circuits 902 and 903. Here, the read/write circuits 904 and 905 receive a read/write control signal from outside the SRAM circuit 900, and read or write data in accordance with the read/write control signal.

The redundancy control circuit 906 receives redundant data from outside the SRAM circuit 900, and controls the A/B selection circuits 902 and 903 to select ports using the redundant data. The redundancy control circuit 906 further controls the A/B selection circuits 909 and 910 to select a word line and to select a word line to be driven to select ports to be used for data reading or writing, by using the redundant data.

The address decoding circuit 907 is a circuit that activates, in accordance with an address input received from outside the SRAM circuit 900, access to a memory cell circuit instructed by the address input.

The word line driving circuit 908 drives word lines connected to the memory cell circuits (including the memory cell circuit 9011) in the memory cell array 901 to make operable the memory cells to which the word lines are connected.

The A/B selection circuits 909 and 910 are circuits that select the word line A or the word line B, and are circuits that select ports to be used for data reading or writing to drive a word line for enabling the ports to be used.

9. Configuration of A/B Selection Circuit 909

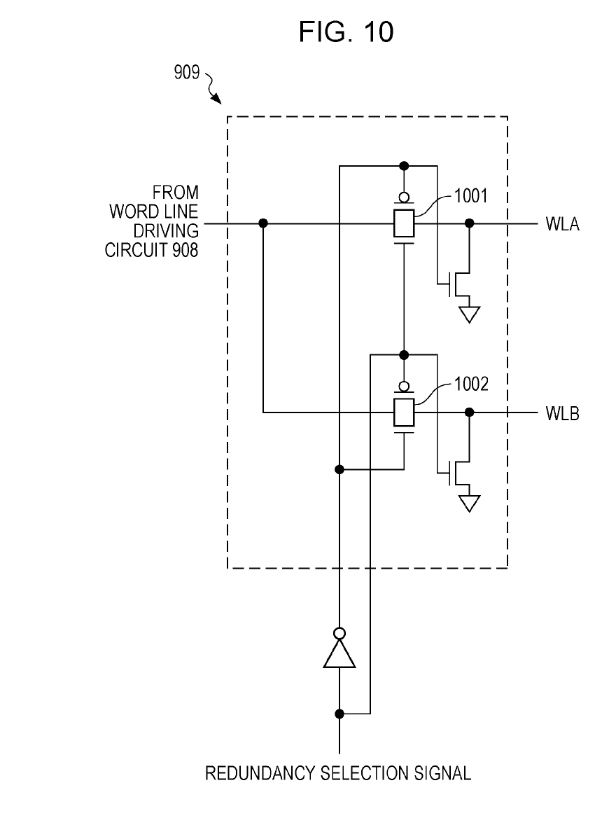

FIG. 10 is a configuration diagram of the A/B selection circuit 909 according to this embodiment. The A/B selection circuit 909 is a circuit that selects the word line A or the word line B, and is a circuit that selects a word line to be driven, in accordance with the redundancy selection signal received from the redundancy control circuit 906.

For example, when the redundancy selection signal is set high (H), a CMOS transmission gate 1001 is brought into conduction, and the word line A is driven. When the redundancy selection signal is set low (L), a CMOS transmission gate 1002 is brought into conduction, and the word line B is driven. Accordingly, only the word line to be used for data reading or writing is driven while unnecessary word lines are not driven. Thus, power consumption may be reduced accordingly.

10. Configuration of SRAM Circuit 1100

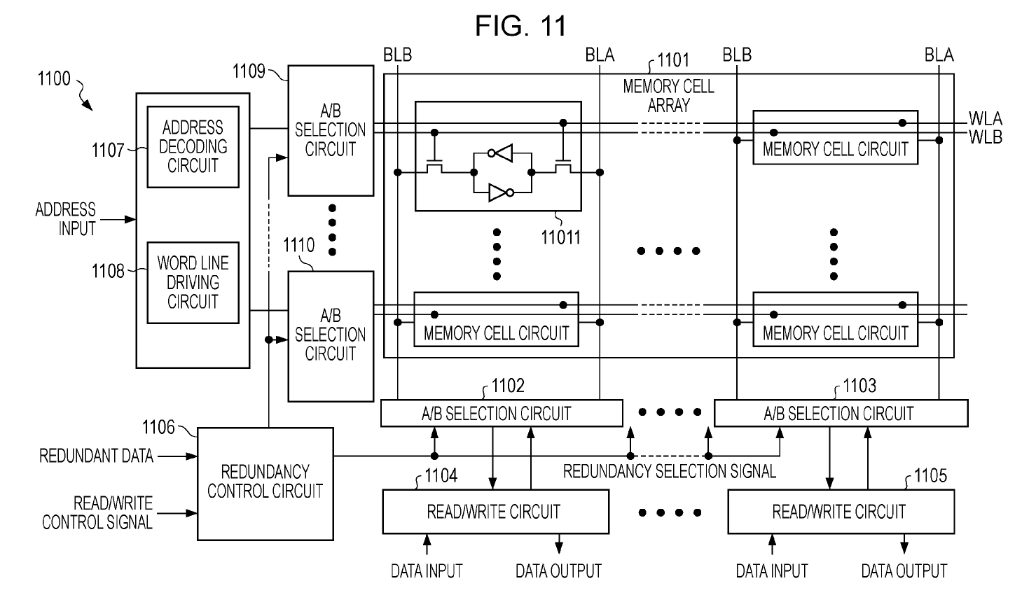

FIG. 11 is a configuration diagram of an SRAM circuit 1100 according to an embodiment. In this embodiment, the SRAM circuit 1100 is constituted by a 6Tr SRAM memory cell circuit 11011 and a plurality of 6Tr memory cell circuits having configurations equivalent to the configuration of the 6Tr SRAM memory cell circuit 11011. Like the SRAM circuit 900, the SRAM circuit 1100 is also provided with word lines, namely, a word line A and a word line B. The SRAM circuit 1100 is configured such that redundant data as well as a read/write control signal is input to a redundancy control circuit 1106. This configuration allows A/B selection circuits 1102, 1103, 1109, and 1110 to select different ports for reading and writing data.

For example, the following configuration may be provided: (1) only the A (or B) port is used for reading and both ports are used for writing, (2) both A and B ports are used for reading and the A (or B) port is used for writing, and (3) one of the A/B ports is selected and used for both reading and writing.

The SRAM circuit 1100 includes a memory cell array 1101, the A/B selection circuits 1102 and 1103, read/write circuits 1104 and 1105, the redundancy control circuit 1106, an address decoding circuit 1107, a word line driving circuit 1108, and the A/B selection circuits 1109 and 1100. The memory cell array 1101 is constituted by the 6Tr memory cell circuit 11011 and a plurality of 6Tr memory cell circuits having configurations equivalent to the configuration of the 6Tr memory cell circuit 11011, and the plurality of 6Tr memory cell circuits are arranged in an array.

The A/B selection circuit 1102 selects ports to be used for data writing or reading from among redundant ports respectively arranged in the plurality of 6Tr memory cell circuits (including the 6Tr memory cell circuit 11011) constituting the memory cell array 1101. The A/B selection circuit 1103 is also a circuit that selects ports to be used for data writing or reading from among the redundant ports.

The read/write circuits 1104 and 1105 are circuits that read or write data using the ports selected by the A/B selection circuits 1102 and 1103. Here, the read/write circuits 1104 and 1105 receive a read/write control signal from outside the SRAM circuit 1100, and read or write data in accordance with the read/write control signal.

The redundancy control circuit 1106 receives redundant data from outside the SRAM circuit 1100, and controls the A/B selection circuits 1102 and 1103 to select ports using the redundant data. The redundancy control circuit 1106 further controls the A/B selection circuits 1109 and 1110 to select a word line and to select a word line to be driven to select ports to be used for data reading or writing, by using the redundant data. Further, the redundancy control circuit 1106 receives a read/write control signal from outside the SRAM circuit 1100, and instructs the A/B selection circuits 1102, 1103, 1109, and 1110 to select ports using the read/write control signal in accordance with data to be read and data to be written.

The address decoding circuit 1107 is a circuit that activates, in accordance with an address input received from outside the SRAM circuit 1100, access to a memory cell circuit instructed by the address input.

The word line driving circuit 1108 drives word lines connected to the memory cell circuits (including the memory cell circuit 11011) in the memory cell array 1101 to make operable the memory cells to which the word lines are connected.

The A/B selection circuits 1109 and 1110 are circuits that select the word line A or the word line B, and are circuits that select ports to be used for data reading or writing to drive a word line for enabling the ports to be used.

11. Configuration of SRAM Circuit 1200

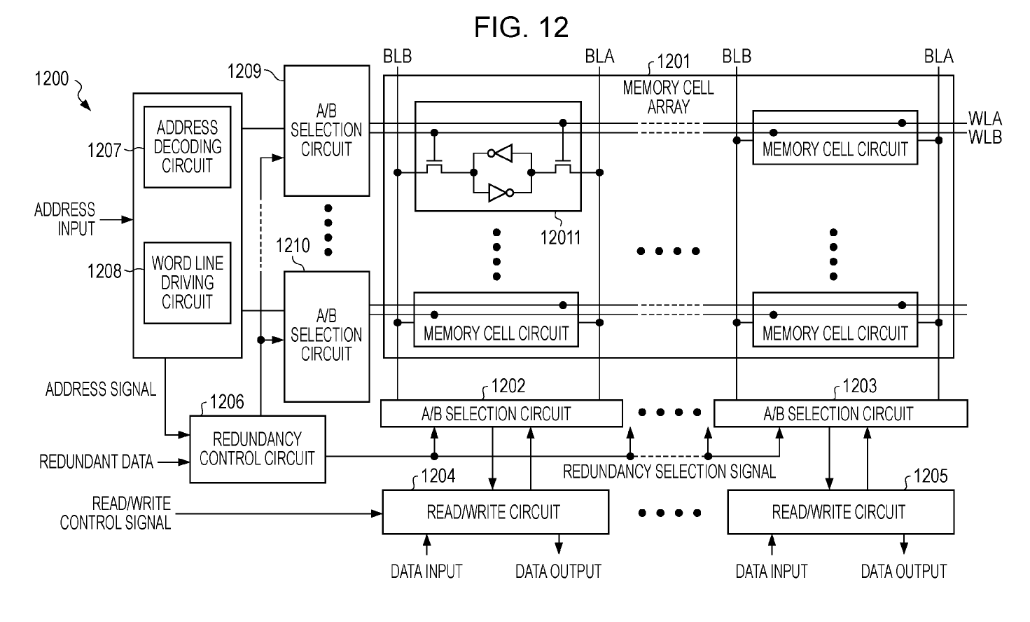

FIG. 12 is a configuration diagram of an SRAM circuit 1200 according to an embodiment. In this embodiment, the SRAM circuit 1200 is constituted by a 6Tr SRAM memory cell circuit 12011 and a plurality of 6Tr memory cell circuits having configurations equivalent to the configuration of the 6Tr SRAM memory cell circuit 12011. Like the SRAM circuits 900 and 1100, the SRAM circuit 1200 is also provided with word lines, namely, a word line A and a word line B. The SRAM circuit 1200 is configured such that an address signal is input to a redundancy control circuit 1206. Accordingly, the SRAM circuit 1200 is configured to change the setting of redundant ports of a memory cell array 1201 in accordance with the address input.

The SRAM circuit 1200 includes the memory cell array 1201, A/B selection circuits 1202 and 1203, read/write circuits 1204 and 1205, the redundancy control circuit 1206, an address decoding circuit 1207, a word line driving circuit 1208, and A/B selection circuits 1209 and 1210. The memory cell array 1201 is constituted by the 6Tr memory cell circuit 12011 and a plurality of 6Tr memory cell circuits having configurations equivalent to the configuration of the 6Tr memory cell circuit 12011, and the plurality of 6Tr memory cell circuits are arranged in an array.

The A/B selection circuit 1202 selects ports to be used for data writing or reading from among redundant ports respectively arranged in the plurality of 6Tr memory cell circuits (including the 6Tr memory cell circuit 12011) constituting the memory cell array 1201. The A/B selection circuit 1203 is also a circuit that selects ports to be used for data writing or reading from among the redundant ports.

The read/write circuits 1204 and 1205 are circuits that read or write data using the ports selected by the A/B selection circuits 1202 and 1203. Here, the read/write circuits 1204 and 1205 receive a read/write control signal from outside the SRAM circuit 1200, and read or write data in accordance with the read/write control signal.

The redundancy control circuit 1206 receives redundant data from outside the SRAM circuit 1200, and controls the A/B selection circuits 1202 and 1203 to select ports using the redundant data. The redundancy control circuit 1206 further controls the A/B selection circuits 1209 and 1210 to select a word line and to select a word line to be driven to select ports to be used for data reading or writing, by using the redundant data. Further, the redundancy control circuit 1206 receives an address signal from the address decoding circuit 1207, and instructs the A/B selection circuits 1202, 1203, 1209, and 1210 to change the setting of redundant ports of the memory cell array 1201 in accordance with the address signal.

The address decoding circuit 1207 is a circuit that activates, in accordance with an address input received from outside the SRAM circuit 1200, access to a memory cell circuit instructed by the address input.

The word line driving circuit 1208 drives word lines connected to the memory cell circuits (including the memory cell circuit 12011) in the memory cell array 1201 to make operable the memory cells to which the word lines are connected.

The A/B selection circuits 1209 and 1210 are circuits that select the word line A or the word line B, and are circuits that select ports to be used for data reading or writing to drive a word line for enabling the ports to be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor storage device comprising:
a memory cell array having memory cells each configured to hold data;
a plurality of N ports;
a port selection circuit that selects M (M<N) ports from among the plurality of N ports based on input select signal; and
a read and write circuit that reads data from the memory cell array or writes data to the memory cell array using the ports selected by the port selection circuit.

2. The semiconductor storage device according to claim 1, further comprising a control circuit that generates the select signal which indicates selecting M ports to control the port selection circuit to select M ports from among the plurality of N ports by the port selection circuit.

3. The semiconductor storage device according to claim 2, wherein the port selection circuit is located before a point at which write data reach the memory cell array.

4. The semiconductor storage device according to claim 2, wherein the port selection circuit is located after a point at which data is read from the memory cell array.

5. The semiconductor storage device according to claim 2, wherein an other port selection circuit is located between a word line and the memory sell array,
wherein the control circuit controls the other port selection circuit to select using word lines.
